(19) United States
(12) Patent Application Publication
(10) Pub. No.: US 2010/0148185 A1
(43) Pub. Date: Jun. 17, 2010

(54) FLIP-CHIP LIGHT-EMITTING DIODE DEVICE

(75) Inventor: Chin-Yuan Hsu, Taipei (TW)

Correspondence Address: RABIN & Berdo, PC, 1101 14TH STREET, NW, SUITE 500, WASHINGTON, DC, 20005, US

(73) Assignee: EVERLIGHT ELECTRONICS CO., LTD., Taipei (TW)

(21) Appl. No.: 12/638,430

(22) Filed: Dec. 15, 2009

(30) Foreign Application Priority Data
Dec. 15, 2008 (TW) 97148866

(51) Int. Cl. H01L 33/32

(52) U.S. Cl. 257/76; 257/79; 257/E33.025

(57) ABSTRACT

A flip-chip light-emitting diode (LED) device is provided. The flip-chip LED device includes a substrate, an n-GaN layer, an epitaxy layer, a p-GaN layer, a first electrode, and a second electrode. The n-GaN layer is formed on a surface of the substrate. The epitaxy layer is formed on the n-GaN layer. The p-GaN layer is formed on the epitaxy layer. The first electrode has a first polarity and is formed on the p-GaN layer. The first electrode substantially covers the p-GaN layer. The second electrode is formed on the n-GaN layer and has a second polarity opposite to the first polarity.

This application claims the benefit of Taiwan application Serial No. 97148866, filed Dec. 15, 2008, the subject matter of which is incorporated herein by reference.

### BACKGROUND OF THE INVENTION

1. Field of the Invention

The invention relates in general to a light-emitting diode (LED) device, and more particularly to a flip-chip LED device for providing better optical extraction efficiency and heat dissipation efficiency.

2. Description of the Related Art

A flip-chip light-emitting method is provided to increase the external optical extraction efficiency, which is the efficiency in extracting the light outside the light-emitting diode chip, of the light-emitting diodes. FIG. 1 shows a cross-sectional view of a conventional flip-chip LED device 10. The LED device 10 includes a substrate 100, an n-GaN layer 110, an epitaxy layer 120, and a p-GaN layer 130. The LED device 10 is bonded to a silicon substrate 102 via the gold stud bumps 112 and 132.

On the part of the flip-chip LED structure, conventional LED crystalline grains are inversely disposed on the substrate, and the contact between the inverse crystalline grains and the substrate solely relies on limited number of gold stud bumps. FIG. 2 shows a top view of the flip-chip LED device 10 of FIG. 1, wherein the silicon substrate 102 is not illustrated. As shown in the diagram, the contact between the crystalline grains 10 and the substrate solely relies on six gold stud bumps 112, 132, so the qualities of conductivity and heat dissipation are restricted. Moreover, the optical extraction efficiency of the above-mentioned flip-chip LED structure is not yet optimized.

### SUMMARY OF THE INVENTION

The invention is directed to a light-emitting diode (LED) device, which increases optical extraction efficiency and heat dissipation efficiency by increasing the contact area of the electrodes.

The invention is further directed to an LED device, which further increases optical extraction efficiency and heat dissipation efficiency by uniformly distributing the light-emitting diodes disposed therein.

According to a first aspect of the present invention, a flip-chip light-emitting diode (LED) device is provided. The flip-chip LED device includes a substrate, an n-GaN layer, an epitaxy layer, a p-GaN layer, a first electrode, and a second electrode. The n-GaN layer is formed on a surface of the substrate. The epitaxy layer is formed on the n-GaN layer. The p-GaN layer is formed on the epitaxy layer. The first electrode has a first polarity and is formed on the p-GaN layer. The first electrode substantially covers the p-GaN layer. The second electrode is formed on the n-GaN layer and has a second polarity opposite to the first polarity.

According to a second aspect of the present invention, an LED device is provided. The LED device includes a substrate, an n-GaN layer, a plurality of epitaxy layers, a plurality of p-GaN layers, a plurality of first electrodes, and a plurality of second electrodes. The n-GaN layer, formed on a surface of the substrate, is saw-toothed and has a plurality of indentations and protrusions which are consecutively disposed. The epitaxy layers are formed on the protrusions of the n-GaN layer. The p-GaN layers are formed on the epitaxy layers. The first electrodes having a first polarity are formed on the p-GaN layers and equally spaced. The second electrodes, which have a second polarity opposite to the first polarity of the first electrodes, are formed on the n-GaN layer and located on two sides of the substrate.

The invention will become apparent from the following detailed description of the preferred but non-limiting embodiments. The following description is made with reference to the accompanying drawings.

### BRIEF DESCRIPTION OF THE DRAWINGS

FIG. 1 shows a cross-sectional view of a flip-chip LED device 10;

FIG. 2 shows a top view of the flip-chip LED device 10 of FIG. 1;

FIG. 3 shows a cross-sectional view of an LED device 30 according to a preferred embodiment of the invention;

FIG. 4 shows a top view of the LED device 30 of FIG. 3;

FIG. 5 shows a cross-sectional view of an LED device 50 according to another preferred embodiment of the invention;

FIG. 6 shows a cross-sectional view of an LED device 60 according to another preferred embodiment of the invention;

FIG. 7 shows a cross-sectional view of an LED device 70 according to another preferred embodiment of the invention;

FIG. 8 shows a cross-sectional view of an LED device 80 according to another preferred embodiment of the invention;

FIG. 9 shows a cross-sectional view of an LED device 90 according to another preferred embodiment of the invention;

FIG. 10 shows a top view of an LED device 40 according to a preferred embodiment of the invention;

FIG. 11 shows a partial cross-sectional view of the LED device 40 of FIG. 10;

FIG. 12 shows a top view of an LED device 42 according to a preferred embodiment of the invention; and

FIG. 13 shows a cross-sectional view of the LED device 42 of FIG. 12.

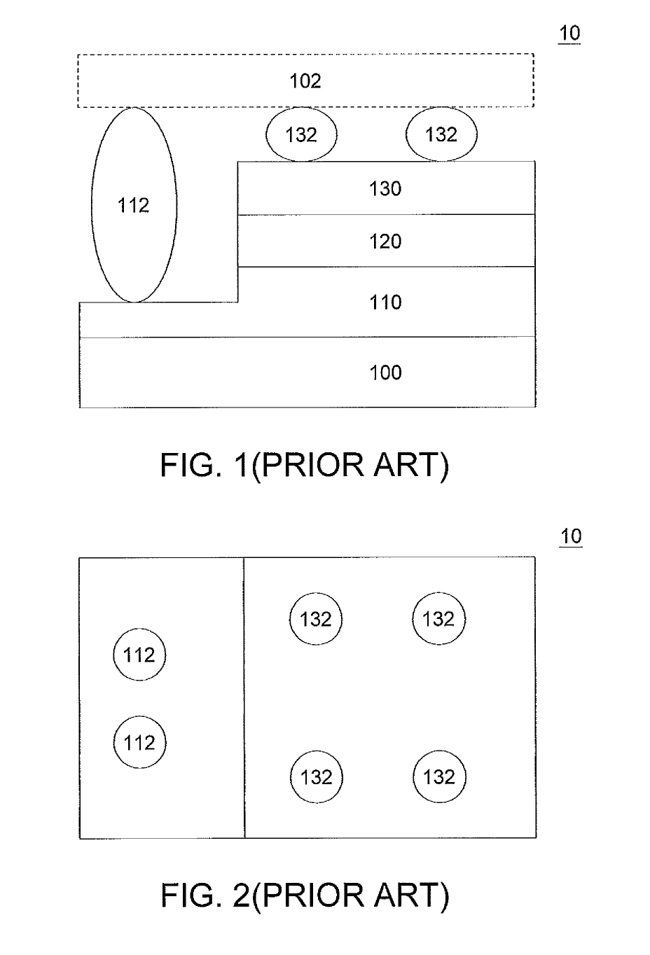

### DETAILED DESCRIPTION OF THE INVENTION

To further elaborate the objects, functions, features and advantages of the invention, a number of preferred embodiments are exemplified below with accompanying drawings.

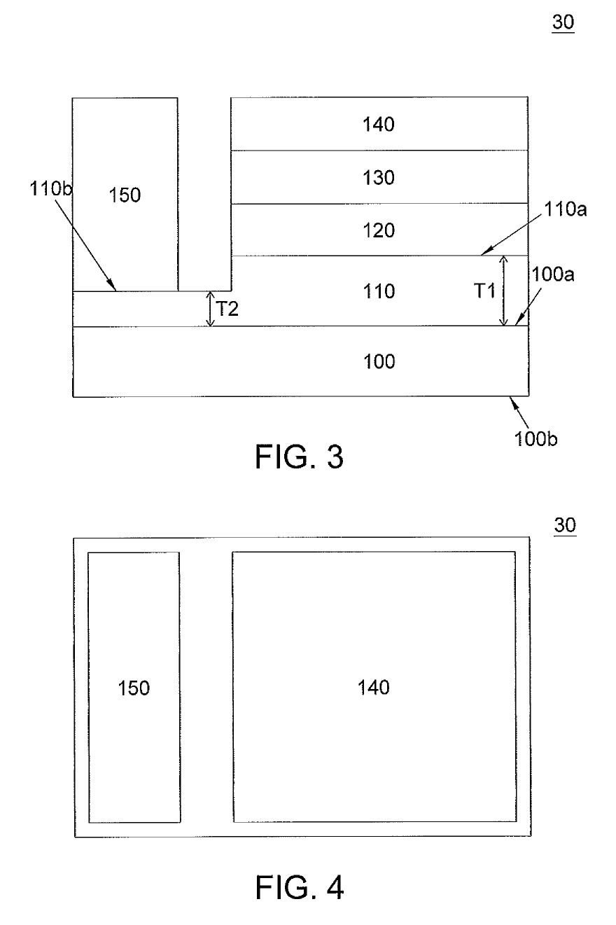

FIG. 3 shows a cross-sectional view of a light-emitting diode (LED) device 30 according to a preferred embodiment of the invention. The LED device 30 includes a substrate 100, an n-GaN layer 110, an epitaxy layer 120, a p-GaN layer 130, a first electrode 140, and a second electrode 150. The substrate 100 has a first surface 100a and a second surface 100b opposite to the first surface 100a. The substrate 100 can be a silicon substrate, a silicon carbide substrate, a ceramic substrate (such as aluminum oxide and aluminum nitride), and a metal substrate (such as copper, copper alloy, aluminum, aluminum alloy, and stainless steel). The n-GaN layer 110 is formed on the first surface 100a of the substrate 100, and has a first thickness T1 and a second thickness T2, wherein the first thickness T1 corresponds to a first surface 110a, and the second thickness T2 corresponds to a second surface 110b. The epitaxy layer 120 is formed on the first surface 110a of the n-GaN layer 110. The p-GaN layer 130 is formed on the epitaxy layer 120. The first electrode 140 is formed on the p-GaN layer 130, and has a first polarity. Preferably, the first electrode 140 substantially and completely covers the p-GaN layer 130. The second electrode 150 is formed on the second surface 110b of the n-GaN layer 110, and has a second polarity opposite to the first polarity of the first electrode 140. Preferably, the second electrode 150 substantially and completely covers the second surface 110b. The n-GaN layer 110, the epitaxy layer 120, and the p-GaN layer 130 are known to anyone who is skilled in the technology of the invention, and are not repeated here. FIG. 4 shows a top view of the LED device 30 of FIG. 3. As indicated in the diagram, the first electrode 140 substantially and completely covers the p-GaN layer 130, and the second electrode 150 substantially and completely covers the second surface 110b. The first electrode 140 and the second electrode 150 can be made from a metal with excellent conductivity and prompt dissipation (such as gold, silver, copper, and aluminum), solder, or eutectic. By increasing the contact area between the first electrode 140 and the second electrode 150, optical extraction efficiency and heat dissipation efficiency for the first electrode 140 and the second electrode 150 are further improved. The reasons are given below. (1) As the contact area of the electrodes increases, the current flowing through a larger area on the surface is uniformly distributed in the LED device 30. Thus, the light-emitting part of the epitaxy layer 120 is more uniformly distributed instead of concentrating in a path like the conventional LED device 10, which uses gold stud bumps and emits the light only at a part of the epitaxy layer 120. (2) The larger contact area of the electrodes, the larger the dissipation area, so the heat dissipation efficiency is increased. In another preferred embodiment, the substrate 100 can be removed and directly flip-chipped on the lead frame of a package (not illustrated) for reducing the thickness of the elements.

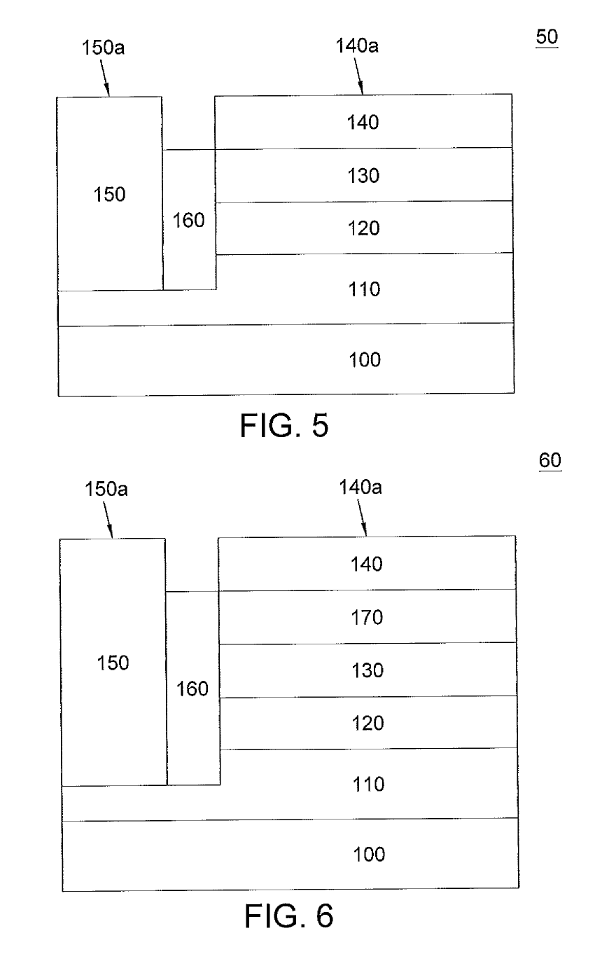

FIG. 5 shows a cross-sectional view of an LED device 50 according to another preferred embodiment of the invention. As indicated in the diagram, the LED device 50 further includes an insulation layer 160 for insulating the second electrode 150, the first electrode 140, the p-GaN layer 130, and the epitaxy layer 120. The surface 140a of the first electrode 140 farther away from the substrate 100 and the surface 150a of the second electrode 150 farther away from the substrate 100 substantially are coplanar.

FIG. 6 shows a cross-sectional view of an LED device 60 according to another preferred embodiment of the invention. As indicated in the diagram, a reflective layer 170 is interposed between the first electrode 140 and the p-GaN layer 130 of the LED device 60. Through the interposition of the reflective layer 170, the light emitted towards the reflective layer 170 is reflected and the light emitting efficiency is further increased. The surface 140a of the first electrode 140 farther away from the substrate 100 and the surface 150a of the second electrode 150 farther away from the substrate 100 substantially are coplanar.

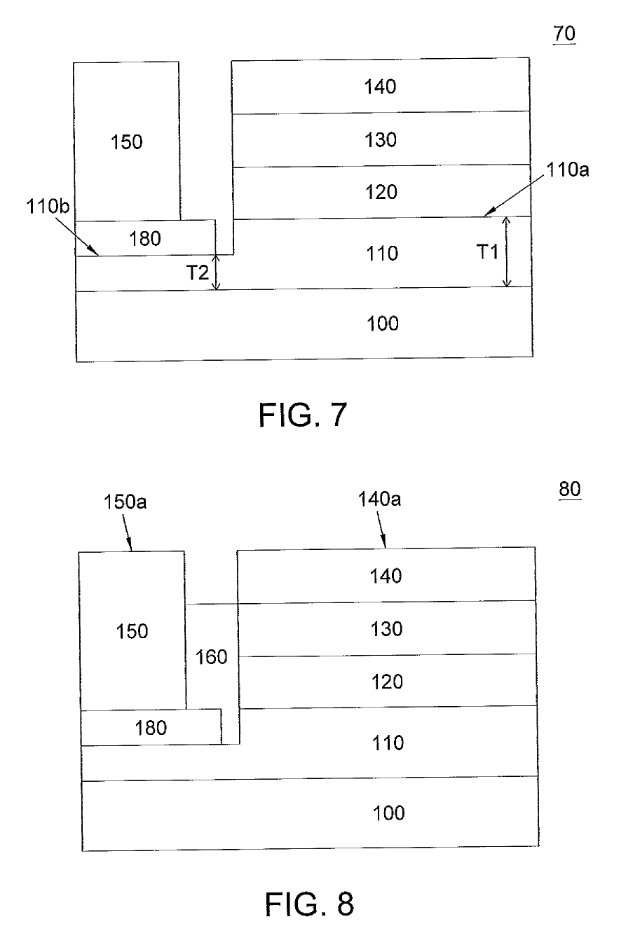

FIG. 7 shows a cross-sectional view of an LED device 70 according to another preferred embodiment of the invention. As indicated in the diagram, the LED device 70 includes a substrate 100, an n-GaN layer 110, an epitaxy layer 120, a p-GaN layer 130, a first electrode 140, an n-metal layer 180, and a second electrode 150. The n-GaN layer 110 is formed on a surface of the substrate 100, and has a first thickness T1 and a second thickness T2, wherein the first thickness T1 corresponds to a first surface 110a, and the second thickness corresponds to a second surface 110b. The epitaxy layer 120 is formed on the first surface 110a of the n-GaN layer 110. The p-GaN layer 130 is formed on the epitaxy layer 120. The first electrode 140 is formed on the p-GaN layer 130, and substantially and completely covers the p-GaN layer 130. The n-metal layer 180, such as a third electrode formed on the second surface 110b, substantially and mostly covers the second surface 110b. The second electrode 150, formed on the n-metal layer 180 and electrically connected to the n-metal layer 180, substantially and mostly covers the n-metal layer 180. The n-metal layer 180 can be made from materials such as Ti/Al, Ti/Al/Ti/Au, Ti/Pt/Au, Cr/Au, and Cr/Pt/Au.

FIG. 8 shows a cross-sectional view of an LED device 80 according to another preferred embodiment of the invention. As indicated in the diagram, the LED device 80 further includes an insulation layer 160 for insulating the second electrode 150 and the first electrode 140, the p-GaN layer 130, the epitaxy layer 120. The surface 140a of the first electrode 140 farther away from the substrate 100 and the surface 150a of the second electrode 150 farther away from the substrate 100 substantially are coplanar.

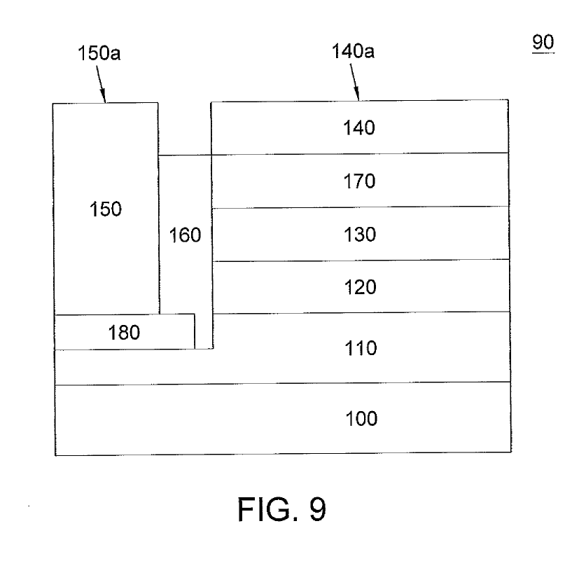

FIG. 9 shows a cross-sectional view of an LED device 90 according to another preferred embodiment of the invention. As indicated in the diagram, a reflective layer 170 is interposed between the first electrode 140 and the p-GaN layer 130 of the LED device 90. Through the disposition of the reflective layer 170, the light emitted towards the reflective layer 170 is reflected and the light emitting efficiency is further increased. The surface 140a of the substrate 100 farther away from the first electrode 140 and the surface 150a of the second electrode 150 farther away from the substrate 100 substantially are coplanar.

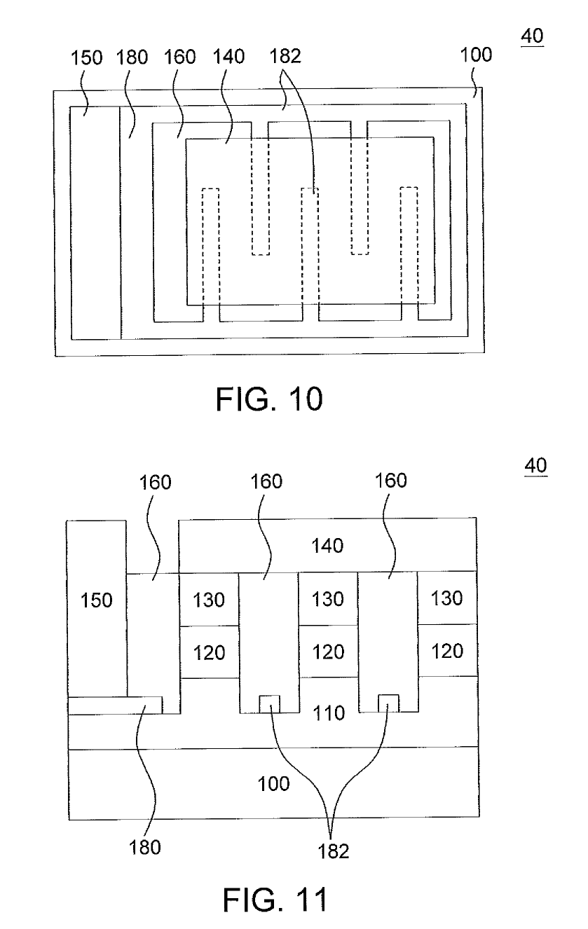

FIG. 10 shows a top view of an LED device 40 according to a preferred embodiment of the invention. As indicated in the diagram, the n-metal layer 180 further includes two extension portions 182 disposed on the surface of the n-GaN layer 110 having the second thickness T2 (referring to FIG. 7). Preferably, the two extension portions 182 are disposed alternately and parallel to each other at a distance. In an embodiment, the extension portions 182 are fin-shaped or grid-shaped, so that the current is further uniformly distributed in the n-GaN layer 110, and optical extraction efficiency and heat dissipation efficiency are increased. FIG. 11 shows a partial cross-sectional view of the LED device 40 of FIG. 10. As indicated in the diagram, apart from increasing optical extraction efficiency and heat dissipation efficiency, the current further provides side light (the left and the right sides of the epitaxy layer 120 of FIG. 11) to further increase light emitting efficiency and make the emitting of the light more uniformly distributed. Anyone who is skilled in the technology of the invention will understand that the LED device can be any of the abovementioned LED devices 30, 50, 60, 70, 80, 90.

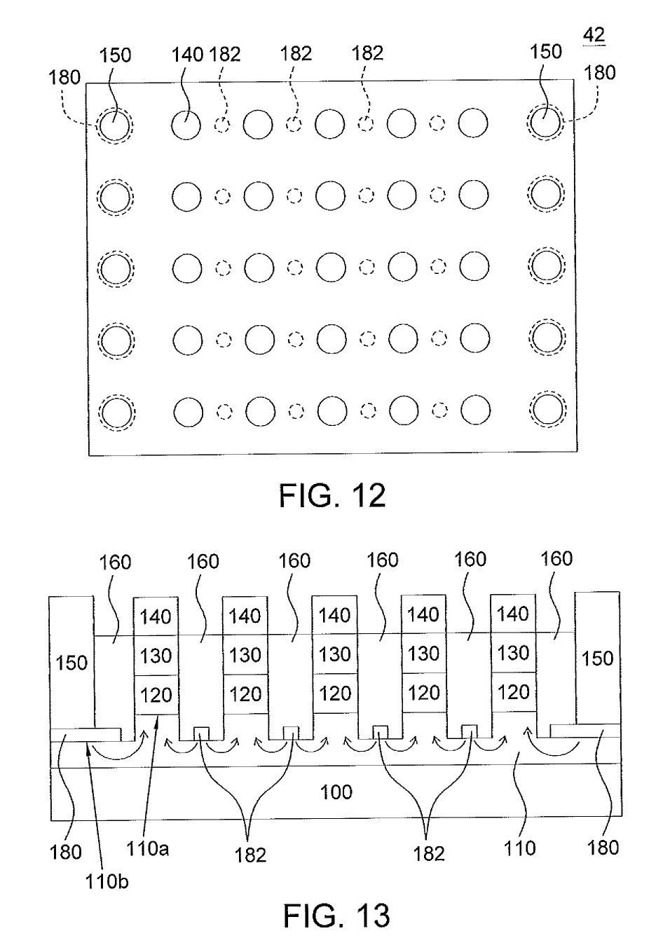

FIG. 12 shows a top view of an LED device 42 according to a preferred embodiment of the invention. FIG. 13 shows a cross-sectional view of the LED device 42 of FIG. 12. The LED device 42 includes a substrate 100, an n-GaN layer 110, a plurality of the epitaxy layers 120, a plurality of p-GaN layers 130, a plurality of first electrodes 140, a plurality of n-metal layers 180, and a plurality of second electrodes 150. The n-GaN layer 110, formed on a surface of the substrate 100, is saw-toothed and has a plurality of indentations (corresponding to smaller thicknesses) and protrusions (corresponding to larger thicknesses), wherein the indentations and the protrusions are consecutively disposed and have a plurality of first thicknesses and second thicknesses, the first thicknesses correspond to a first surface 110a, and the second thicknesses correspond to a second surface 110b. Each of the epitaxy layers 120 is formed on a corresponding first surface 110a of the n-GaN layer 110. Each of the p-GaN layers 130 is formed on a corresponding epitaxy layer 120. Each of the first electrodes 140 is formed on a corresponding p-GaN layer 130, and substantially and completely covers a corresponding p-GaN layer 130. Each of the n-metal layers 180 is formed on a corresponding second surface 110b, and substantially mostly covers a corresponding second surface 110b. Each of the second electrodes 150 is formed on a corresponding n-metal layer 180, and substantially and completely covers a corresponding n-metal layer 180. The first electrodes 140 and the second electrodes 150 are arranged in the form of an array. Besides, the n-metal layer 180 includes an extension portion 182 embedded into a part of the n-GaN layer 110, so that the current is further uniformly distributed in the n-GaN layer 110, and optical extraction efficiency and heat dissipation efficiency are improved. The current further provides side light (the left and the right sides of the epitaxy layer 120 of FIG. 13) to further increase light emitting efficiency and make the emitting of the light more uniformly distributed. Anyone who is skilled in the technology of the invention will understand that the LED device may employ any of the above-mentioned LED devices 30, 50, 60, 70, 80, 90. In a preferred embodiment, the shape of each of the first electrodes 140 and second electrodes 150 can be a square, a circle, a hexagon, or an octagon.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light-emitting diode (LED) device, comprising:
a substrate having a first surface and a second surface opposite to the first surface;
an n-GaN layer formed on the first surface of the substrate;
an epitaxy layer formed on the n-GaN layer;
a p-GaN layer formed on the epitaxy layer;
a first electrode having a first polarity and formed on the p-GaN layer, wherein the first electrode substantially covers the p-GaN layer; and
a second electrode having a second polarity opposite to the first polarity of the first electrode, wherein the second electrode is formed on the n-GaN layer.

2. The LED device according to claim 1, further comprising:
an insulation layer disposed between the first electrode and the second electrode for insulating the first electrode and the second electrode.

3. The LED device according to claim 1, wherein the first electrode and the second electrode substantially are coplanar.

4. The LED device according to claim 1, further comprising a reflective layer disposed between the first electrode and the p-GaN layer.

5. The LED device according to claim 4, further comprising an insulation layer disposed between the first electrode and the second electrode for insulating the first electrode and the second electrode.

6. The LED device according to claim 5, wherein the first electrode and the second electrode substantially are coplanar.

7. The LED device according to claim 1, further comprising a third electrode disposed on the n-GaN layer and located between the second electrode and the n-GaN layer, and the third electrode and the second electrode have the same polarity.

8. The LED device according to claim 7, further comprising an insulation layer disposed between the first electrode and the second electrode for insulating the first electrode and the second electrode.

9. The LED device according to claim 7, wherein the first electrode and the second electrode substantially are coplanar.

10. The LED device according to claim 7, wherein the third electrode has a first extension portion and a second extension portion, which are extended towards the same direction from the third electrode and are disposed on the n-GaN layer, and the first extension portion and the second extension portion are alternately disposed and parallel to each other at a distance.

11. A light-emitting diode (LED) device, comprising:
a substrate having a first surface and a second surface opposite to the first surface;
an n-GaN layer formed on the first surface of the substrate, wherein the n-GaN layer is saw-toothed and has a plurality of indentations and protrusions which are consecutively disposed;
a plurality of epitaxy layers respectively formed on the protrusions of the n-GaN layer;
a plurality of p-GaN layers respectively formed on the epitaxy layers;
a plurality of first electrodes having a first polarity and respectively formed on the p-GaN layers, wherein the first electrodes are equally spaced; and
a plurality of second electrodes having a second polarity opposite to the first polarity of the first electrodes, wherein the second electrodes are formed on the n-GaN layer and located on two sides of the substrate.

12. The LED device according to claim 11, wherein the first electrodes and the second electrodes are arranged in the form of an array, and the first electrodes and the second electrodes are mutually electrically connected.

13. The LED device according to claim 11, further comprising a plurality of insulation layers respectively disposed between the first electrodes and the second electrodes for insulating each first electrode and each second electrode.

14. The LED device according to claim 13, wherein the first electrodes and the second electrodes substantially are coplanar.

15. The LED device according to claim 14, wherein the shape of each of the first electrodes and the second electrodes is a square, a circle, a hexagon, or an octagon.
